(19) United States
(12) Patent Application Publication
(10) Pub. No.: US 2026/0160785 A1
(43) Pub. Date: Jun. 11, 2026

(54) TEST PROBE TOUCHDOWNS ON GROUPS OF μBUMPS

(71) Applicant: Advanced Micro Devices, Inc., Santa Clara, CA (US)

(72) Inventors: David Gardner KING, Lakeway, TX (US); Omkar Deepak GUPTE, Buda, TX (US); Xin Reng FOO, Singapore (SG)

(21) Appl. No.: 18/973,518

(22) Filed: Dec. 9, 2024

(51) Int. Cl. G01R 1/073

(52) U.S. Cl. CPC G01R 1/07307

(57) ABSTRACT

Improved reliability in testing integrated circuit (IC) dice use groups of μBumps clustered together and forming areas sufficiently large so that test probes reliably make contact to the groups of μBumps for testing of circuit nodes connected thereto. Each group of μBumps defines a landing zone for the test probes and electrical connections to the circuit nodes. The shape of a landing zone may be round, square or rectangular. The number of μBumpsin a landing zone may be at least three. A μBump is a conductive metal column having solder at one end. A portion of each μBump may protrude through a redistribution layer (RDL), wherein the distance therefrom of the μBump ends is substantially the same (coplanar). Shapes and sizes of test probe tips may be selected to facilitate reliable electrical connection to each group of μBumps coupled to the circuit nodes, e.g., power, ground and signal nets.

### TECHNICAL FIELD

Embodiments of the present disclosure generally relate to testing of an integrated circuit wafer and dice, and in particular, to reliably making contact to groups of μBumps with test probes for testing of circuit nodes connected to those groups of μBumps.

### BACKGROUND

Comprehensive testing of integrated circuit wafers and dice has become more difficult and expensive because of the ever-decreasing component dimensions due to increased circuit densities. μBumps located on the surface of a face of the wafer/dice are used for interconnection between other stacked dice, interposers, bridge dies and chiplets. These μBumps may also be used as contact points for circuit testing of the wafer/dice circuit nodes before final assembly of an integrated circuit package. Test probe needles may be adapted to come into contact with the μBumps for connecting the die circuit nodes under test to a test fixture.

With present day technologies, μBump pitches may be less than 45 micrometers and at a high count on the face of the die. A μBump diameter may be about 25 micrometers. Commonly used test probe needles are only proven down to approximately a 90-micrometer pitch. In addition, test probe needles available today are larger than future planned μBump pitches. Present day μBump pitches may be hard to access by general use test probe needles. A common solution to this is to use “sacrificial probe pads for circuit testing.” These sacrificial probe pads are larger than the μBumps, but they also come with challenges. The sacrificial probe pads don't have bumps on them so it's hard to probe through the forest of μBumps surrounding them. As a result, there are design rules establishing using about a 50 micrometer keep-out zone around these sacrificial probe pads. Currently utilized sacrificial probe pads are made of aluminum and adapted for connection to testing circuits using pointed test probe needles. These sacrificial test pads incur additional processing expense and use top level metal real estate that could be used for other purposes, such as μBumps and routing metal.

### SUMMARY

In one example of the disclosure, a method for testing an integrated circuit (IC) wafer having a plurality of IC dice includes selecting locations of μBump groups of each of the plurality of IC dice for testing of circuit nodes coupled to each μBump group. Positioning test probe tips over the selected locations of the μBump groups. Contacting each of the μBump groups with respective ones of the test probe tips. Testing the circuit nodes coupled to each of the μBump groups through the respective ones of the test probe tips. Removing the test probe tips from the μBump groups after testing the circuit nodes coupled thereto. Then evaluating the circuit node test results.

In one example of the disclosure, an integrated circuit (IC) wafer includes a plurality of IC dice. Each of the plurality of IC dice includes a substrate having a plurality of electronic circuits, a redistribution layer (RDL) on the substrate and a plurality of μBumps having portions thereof in the RDL and substantially perpendicular to a face thereof. The electronic circuits have circuit nets thereof coupled to respective groups of the μBumps.

### BRIEF DESCRIPTION OF THE DRAWINGS

So that the manner in which the above recited features of the present invention can be understood in detail, a more particular description of the invention, briefly summarized above, may be had by reference to examples, some of which are illustrated in the appended drawings. It is to be noted, however, that the appended drawings illustrate only typical examples of this invention and are therefore not to be considered limiting of its scope, for the invention may admit to other equally effective examples.

FIG. 1 illustrates a representative schematic plan view of a semiconductor integrated circuit (IC) wafer comprising a plurality of IC dice, according to an example.

FIG. 2 illustrates a representative expanded schematic plan view of an IC die of the IC wafer shown in FIG. 1, according to an example.

FIG. 3 illustrates a representative schematic elevational cross-section view of the IC die shown in FIG. 2, according to an example.

FIGS. 4A, 4B and 4C illustrate representative schematic plan views of μBump groups, and test probe targets and landing zones, according to examples.

FIG. 5 illustrates a representative schematic elevational cross-section view showing planarity of the μBumps, according to an example.

FIG. 6 illustrates a representative schematic elevational cross-section view of a group of μBumps and a test probe in contact therewith, according to an example.

FIG. 7 illustrates a representative schematic elevational cross-section view of a group of μBumps and a test probe having a rounded tip in contact therewith, according to an example.

FIG. 7A illustrates a representative schematic plan view of a group of four μBumps and a test probe tip smaller than the test probe landing zone, according to an example.

FIG. 7B illustrates a representative schematic elevational cross-section view of a group of μBumps and a test probe having a tip smaller than the test probe landing zone, according to an example.

FIG. 7C illustrates a representative schematic elevational cross-section view of a group of μBumps and a test probe having a rounded tip smaller than the test probe landing zone, according to an example.

FIG. 8 illustrates a representative schematic plan view of a plurality μBump groups, four to a group, and test probe targets and landing zones, according to an example.

FIG. 9 illustrates a representative schematic plan view of a plurality μBump groups, four to a group, and test probe targets and landing zones, according to another example.

FIG. 10 illustrates a representative schematic plan view of a plurality μBump groups, three to a group, and test probe targets and landing zones, according to an example.

FIG. 11 illustrates a representative schematic elevational cross-section view of an IC package, according to an example.

FIG. 12 illustrates a prior art schematic plan view of an IC die having sacrificial probe pads located between μBumps.

FIG. 13 illustrates a representative schematic flow diagram for testing an IC die using μBump groups and test probes in electrical communications with the μBump groups, according to an example.

To facilitate understanding, identical reference numerals have been used, where possible, to designate identical elements that are common to the figures, and a lower-case letter added where the elements are substantially the same. It is contemplated that elements of one embodiment may be beneficially incorporated in other embodiments.

### DETAILED DESCRIPTION

Various features are described hereinafter with reference to the drawing figures. It should be noted that the drawing figures may or may not be drawn to scale and that the elements of similar structures or functions are represented by like reference numerals throughout the drawing figures. It should be noted that the drawing figures are only intended to facilitate the description of the features of the examples. They are not intended as an exhaustive description of the examples below or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described. To facilitate understanding, like elements in the drawing figures will be represented by like numbers, and similar elements will be represented by like numbers with a different lower-case letter suffix. It is contemplated that elements of one embodiment may be beneficially incorporated in other embodiments. Referring now to the drawing figures, the details of examples are representative layouts schematically illustrated.

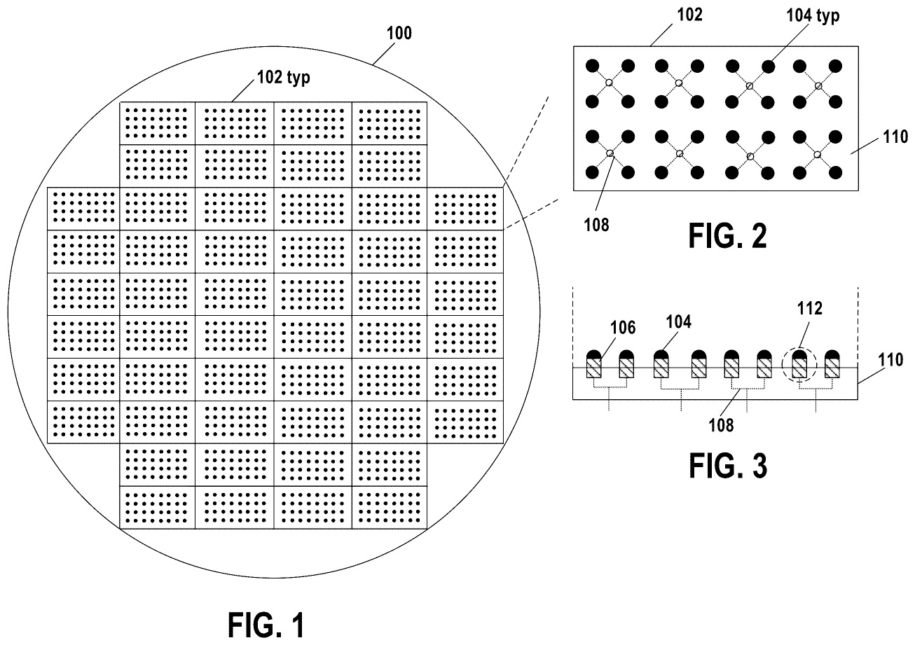

Referring to FIG. 1, depicted is a representative schematic plan view of a semiconductor integrated circuit (IC) wafer comprising a plurality of IC dice, according to an example. An integrated circuit (IC) wafer 100, may comprise a plurality of IC dice 102 having a plurality of electronic circuits therein. The plurality of IC dice 102 of the IC wafer 100 may be tested together before singulation (separation of each of the IC dice 102) or after singulation, wherein each IC die 102 is then tested individually.

Referring to FIGS. 2 and 3, depicted are representative expanded schematic plan and elevational cross-section views of an IC die of the IC wafer shown in FIG. 1, according to an example. Each IC die 102 has a plurality of μBumps 112 connected together in groups (four to a group shown in FIG. 2) with electrically conductive interconnections 108 (metallization) supported in a redistribution layer(s) (RDL) 110. Each μBump 112 comprises a conductive metal column 106 having a cap of solder 104 at one end thereof. The cap of solder 104 and first portions of the conductive metal columns 106 are outside of a surface of the RDL 110. Second portions of the conductive metal columns 106 are in the RDL 110 and perpendicular to a face thereof. The conductive metal column 106 may comprise, for example but is not limited to, multiple metal layers (Cu/Ni/Cu) and the cap of solder 104 at one end thereof. The cap of solder 104 may comprise, for example but is not limited to, SnAg (tin-silver) and SnCu (tin-copper). Each group of μBumps 112 may be coupled, through the electrically conductive interconnections 108, to respective circuit nets (not shown) e.g., power, ground and signals. These circuit nets are connected to electronic circuits (not shown). Each group of μBumps 112 may be used for coupling test probes to the respective circuit nets for testing of the electronic circuits connected thereto.

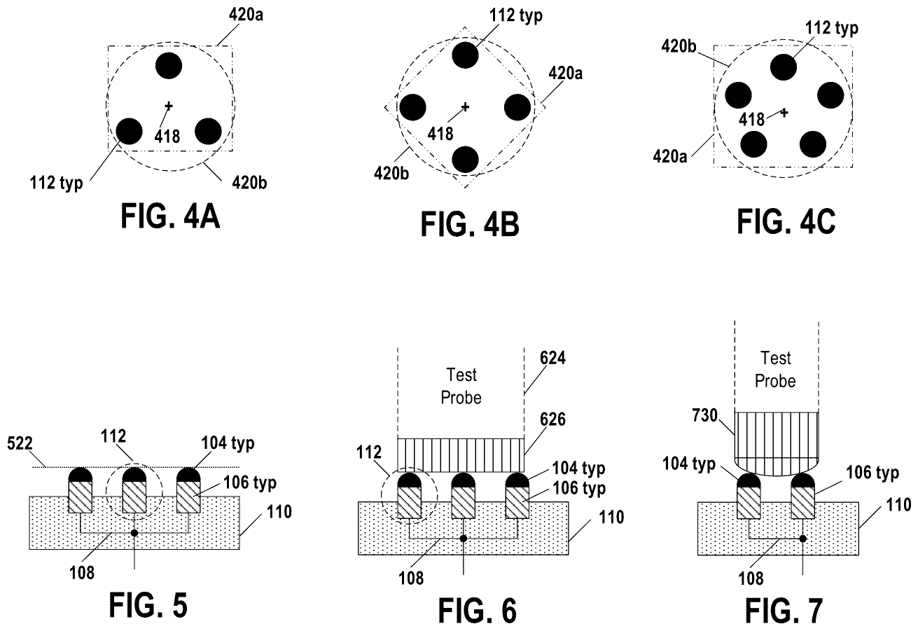

Referring to FIGS. 4A, 4B and 4C, depicted are representative schematic plan views of μBump groups and test probe landing zones, according to examples. FIG. 4A shows a group of three μBumps 112 organized in a triangle shape within a landing zone 420. FIG. 4B shows a group of four μBumps 112 organized in a square shape within a landing zone 420. FIG. 4C shows a group of five μBumps 112 organized in a pentagon shape within a landing zone 420. The landing zone 420 may be substantially square or rectangular (420a) or substantially circular (420b) and, preferably, match up to the shape of the test probe tip. A test probe target 418 may be equidistant between the μBumps 112 of a group and visually created by a test probe placement system (not shown). It is contemplated and within the scope of this disclosure that other numbers of μBumps 112 in a group and organized in appropriate shapes may be used by one having ordinary skill in the art of IC probe testing and the benefit of this disclosure.

Referring to FIG. 5, depicted is a representative schematic elevational cross-section view showing planarity of the μBumps, according to an example. By using the same size μBumps 112 throughout the die 102, planarity, represented by the line 522, may be maintained. Requiring some μBumps to be larger (not shown) for contact with a test probe would be difficult to maintain planarity of the surface of the μBumps for connection assembly with other stacked dice, interposers, bridge dies and chiplets after testing. Thus, by grouping a plurality of small μBumps that are substantially the same size and height above the surface of the RDL 110 (planar), testing of circuit nodes connected thereto and assembly with other devices thereafter are greatly simplified since no further planarity processing is necessary.

Referring to FIG. 6, depicted is a representative schematic elevational cross-section view of a group of μBumps and a test probe in contact therewith, according to an example. A test probe 624 having a tip 626 larger than an end of a single μBump 112 may be utilized for testing purposes since a group of μBumps 112 may be provided in a landing zone 420 for the tip 626. The tip 626 does not have to register exactly on top of the group of μBumps 112 for connecting to a circuit node under test. A respective circuit node (not shown) may be connected to the group of μBumps 112 with the electrically conductive interconnections 108. The tip 626 of the test probe 624 may be substantially flat, rounded or any shape that facilitates reliable connection to the group of μBumps 112.

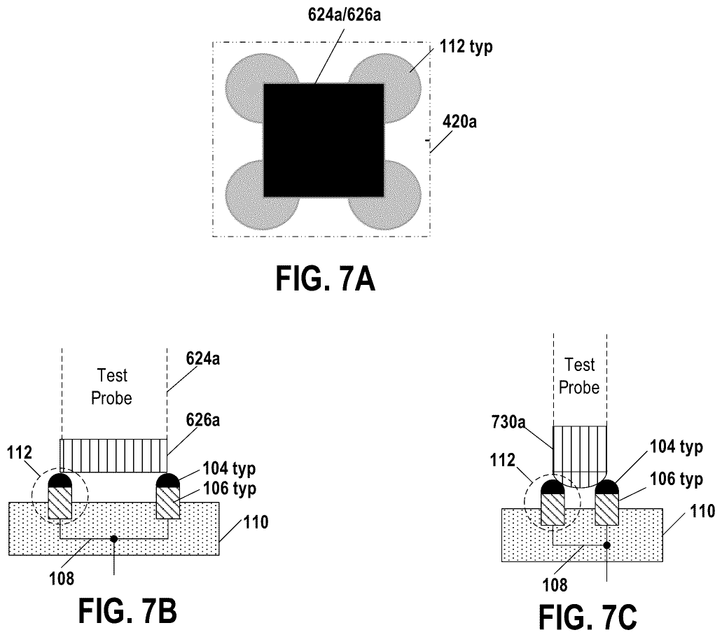

Referring to FIG. 7, depicted is a representative schematic elevational cross-section view of a group of μBumps and a test probe having a rounded tip in contact therewith, according to an example. A test probe 730 having a rounded tip may be advantageous for a reliable and low resistance connection to the group of μBumps 112 shown in FIG. 4. However, it is contemplated and within the scope of this disclosure that other numbers of μBumps 112 in a group and organized in appropriate shapes may be used by one having ordinary skill in the art of IC probe testing and the benefit of this disclosure. The protrusion of portions of the group of μBumps 112 through the RDL 110 may function as an inverted crown to help self-register the tip of the probe 730 onto the protruding ends of the μBumps 112.

Referring to FIG. 7A, depicted is a representative schematic plan view of a group of four μBumps and a test probe tip smaller than the test probe landing zone, according to an example. A test probe tip 626a smaller than the test probe landing zone 420 may be accommodated so long as a reliable electrical connection can be made to at least one of the μBumps 112 of a group. Preferably, the test probe tip 626a bridges and comes into contact with all of the μBumps 112 in the group.

Referring to FIG. 7B, depicted is a representative schematic elevational cross-section view of a group of μBumps and a test probe having a tip smaller than the test probe landing zone, according to an example. The test probe tip 626a is substantially flat, and bridges and comes into contact with the μBumps 112. If registration of the test probe tip 626a is slightly off of the test probe target 418 at least some of the μBumps 112 of a group will still make electrical contact with the flat portion of the test probe tip 626a.

Referring to FIG. 7C, depicted is a representative schematic elevational cross-section view of a group of μBumps and a test probe having a rounded tip smaller than the test probe landing zone, according to an example. The tip of the test probe 730a may be rounded and aligned with the μBumps 112 by a forcing action of the μBumps 112 acting as an “inverted crown” when coming into contact with the rounded tip of the test probe 730a.

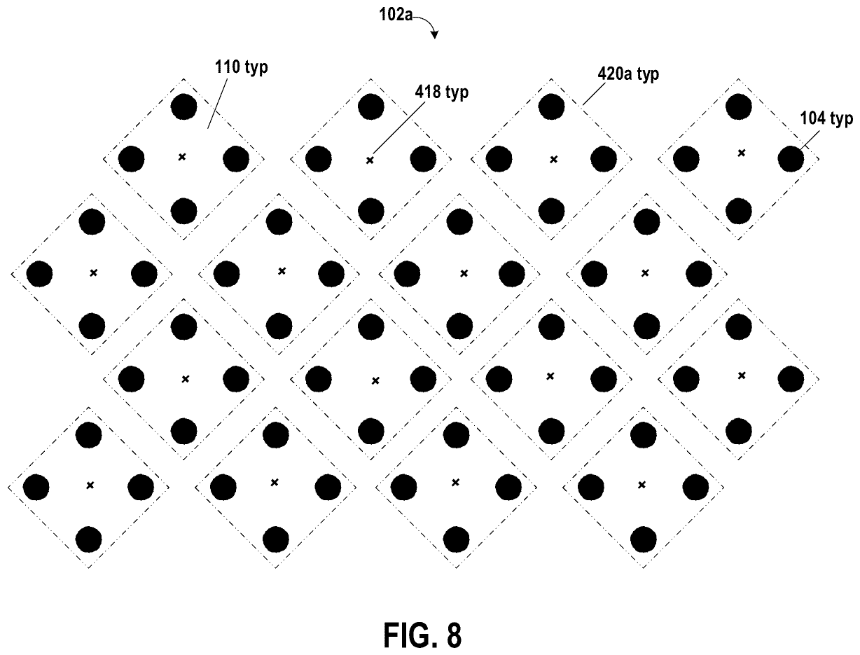

Referring to FIG. 8, depicted is a representative schematic plan view of a plurality μBump groups, four to a group, and test probe targets and landing zones, according to an example. A plurality of μBumps 112 are arranged four to a group in a square/rectangle landing zone 420a layout. Each group of four μBumps 112 are further arranged in diagonal patterns on the face of the IC die 102.

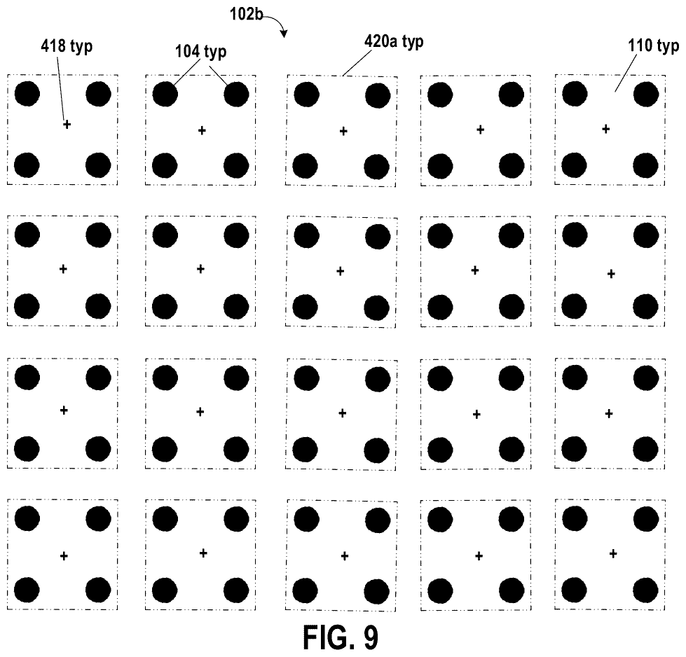

Referring to FIG. 9, depicted is a representative schematic plan view of a plurality μBump groups, four to a group, and test probe targets and landing zones, according to another example. A plurality of μBumps 112 are arranged four to a group in a square/rectangle landing zone 420a layout. Each group of four μBumps 112 are further arranged in rows and columns on the face of the IC die 102.

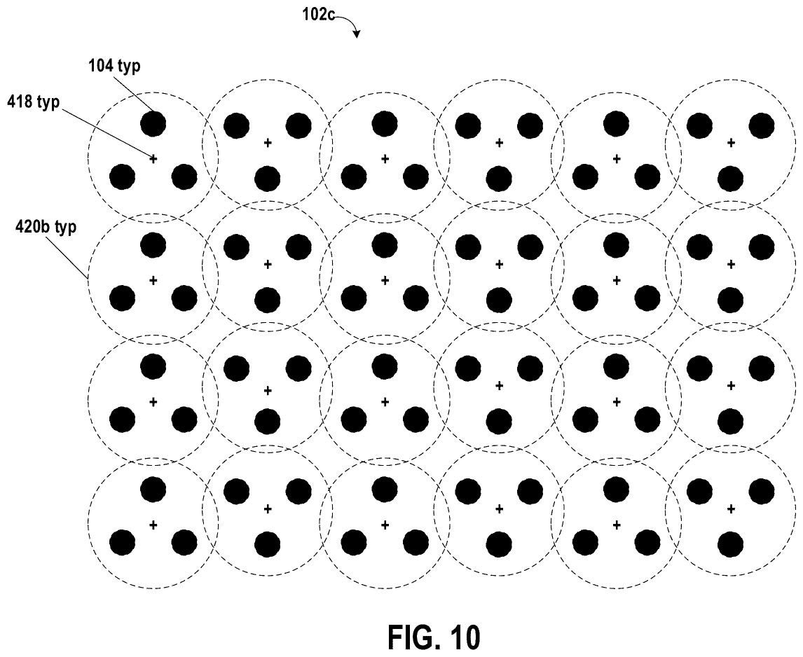

Referring to FIG. 10, depicted is a representative schematic plan view of a plurality μBump groups, three to a group, and test probe targets and landing zones, according to an example. A plurality of μBumps 112 are arranged three to a group in a circular landing zone 420b layout. Each group of three μBumps 112 are further arranged in linear x/y patterns (rows/columns) on the face of the IC die 102.

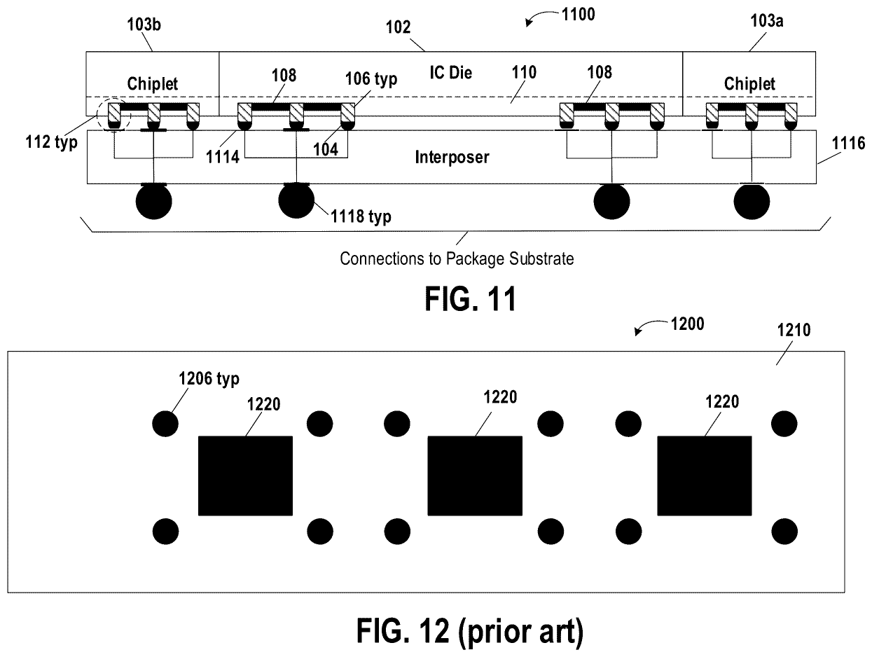

Referring to FIG. 11, depicted is a representative schematic elevational cross-section view of an IC package, according to an example. An IC package, generally represented by the numeral 1100, may comprise at least one IC die 102, at least one chiplet 103 and an interposer substrate 1116. After testing of the at least one IC die 102 and the at least one chiplet 103, they may be fabricated into an IC package 1100. The solder 104 at the ends of the μBumps 112 of the IC die 102 and the at least one chiplet 103 may be attached to connection pads 1114 on the interposer substrate 1116 which may be coupled to a C4 ball grid array 1118 on an opposite side of the interposer substrate 1116. The C4 ball grid array 1118 may be connected to a package substrate (not shown), which may be coupled to a ball grid array (BGA) (not shown) which is used to connect the package substrate to a system printed circuit board (PCB—not shown).

The at least one IC die 102 may be, for example but is not limited to, one or more of any combination of a microcontroller, a microprocessor, a mixed signal processor, a central processing unit (CPU), a programmable logic array (PLA), an application specific integrated circuit (ASIC), a digital signal processor (DSP), a graphics processing unit (GPU), a field programmable gate array (FPGA), neural processing unit and tensor processing unit. The chiplets 103 may include the aforementioned functions of the IC die 102 and may further comprise an arithmetic processing unit, memory, communications interface, programmable logic array, and the like. More IC dice 102 and/or chiplets 103 may be stacked on the chiplets 103 and IC die 102 shown in FIG. 11, and connected together with the aforementioned and described μBumps 112 and connection pads 1114 to produce hybrid bonded stacked dies.

Referring to FIG. 12, depicted is a prior art schematic plan view of an IC die having sacrificial probe pads located between μBumps. An IC die, generally represented by the numeral 1200, may comprise sacrificial probe pads 1220 located between μBumps 1206 and may be embedded in the oxide of the RDL 1210. The sacrificial probe pads 1220 generally are aluminum and large enough in area for standard pointed needle test probes to penetrate the oxide and make contact thereto. Surface area of the IC die 1200 is lost due to having to provide space for the sacrificial probe pads 1220. According to the teachings of this disclosure, elimination of the need for sacrificial probe pads 1220 frees up the area of an IC die (e.g., IC die 102, FIG. 2) normally required therefor, and provides additional useful areas for more test/connection μBumps 112.

Novel features and advantages, according to the teachings of this disclosure, of having μBumps 112 grouped together in a landing zone 420 area and coupled to respective circuit (signal, power, ground) nodes is that the landing zones 420 and locations thereof formed by each group of μBumps 112 may substantially match test probe tip size and ease of placement thereof. Another advantage is that the test probe tip upon touchdown contacts multiple μBumps 112 of a group coupled to a respective circuit net. This provides for self-registration of a rounded test probe tip 730 to improve electrical continuity and extend test probe tip life. Mechanical “touchdown” stress from the test probe tip is distributed to multiple μBumps 112 of a group in a landing zone 420. Test probe auto registration software and camera adjustment to a group of μBumps 112 by visualizing an equidistant point, e.g., test probe target 418, between the μBumps 112 of a group instead of individual μBumps 112 improves test connection position determination reliability and repeatability. The μBump 112 pitches (distance between μBumps) may be equal to or less than 45 micrometers, and substantially the entire surface of the IC die 102 may be utilized since no sacrificial probe pads 1220 are required. Planarity of the ends of the μBumps 112 are easily maintained since all of the μBumps 112 are substantially the same diameter and the solder 104 at the exposed ends of the μBumps 112 will be substantially the same thickness. The solder 104 may be made of, but is not limited to, is SnAg (tin-silver) and SnCu (tin-copper).

Further advantages: Elimination of sacrificial test pads and associated processing expense and cycle time. Since all μBumps 112 are above the passivation layer, there is no need to fit pointed tips on the test probes to make openings in the passivation layer for electrical contact with the sacrificial test pads underneath the passivation layer. All μBumps 112 and redistribution layer (RDL) 110 follow consistent design rules. Improved topology and area utilization through elimination of multi-pitch/size bumps in RDL layers, e.g., no sacrificial test pads-μBump spacing issues. Relatively robust test probe landing zones comprising a plurality of μBumps that are electrically connected together and to a circuit node. Elimination of sacrificial test pads and required SiN passivation layer over the sacrificial test pads. μBumps used for testing and connections are planar and at the same distance from a face of the IC die. The plurality of μBump groups may be adapted to be optimized for alternative test probe tip sizes if required for pitch, resistance, or impedance.

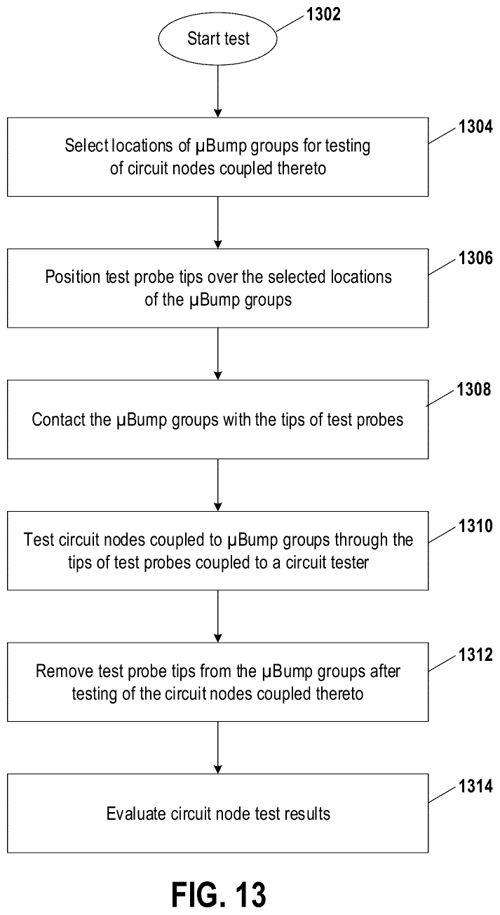

Referring to FIG. 13, depicted is a representative schematic flow diagram for testing an IC die using μBump groups and test probes in electrical communications with the μBump groups, according to an example. In step 1302 an IC die or IC wafer test starts. In step 1304 locations of μBump groups are selected for testing of circuit nodes coupled thereto. In step 1306 a plurality of test probes are positioned over the locations of the μBump groups selected. In step 1308 the plurality of test probes are moved so that the tips thereof contact the selected μBump groups and are in electrical communications therewith. In step 1310 the circuit nodes coupled to the selected μBump groups are tested. In step 1314 test results of the circuit nodes are evaluated.

In the examples disclosed hereinabove, the various semiconductor dice are illustrated or otherwise presumed to be “face down” (e.g., back end of line-BEOL metal layers facing toward the bottom of the stack, bulk silicon/backside facing upward toward the top of the stack). However, different examples may utilize one or more chiplets or other silicon components in “face up” orientations as well.

As will be appreciated by one skilled in the art and having the benefit of this disclosure, the embodiments disclosed herein may be embodied as a system, method, apparatus, or computer programmed product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

While the foregoing is directed to embodiments of the present invention, other and further embodiments of the invention may be devised without departing from the basic scope thereof, and the scope thereof is determined by the claims that follow.

What is claimed:

1. A method for testing at least one integrated circuit (IC) die, said method comprising:
selecting locations of μBump groups of at least one IC die for testing of circuit nodes coupled to each μBump group;
positioning test probe tips over the selected locations of the μBump groups;
contacting each of the μBump groups with respective ones of the test probe tips;
testing the circuit nodes coupled to each of the μBump groups through the respective ones of the test probe tips;
removing the test probe tips from the μBump groups after testing the circuit nodes coupled thereto; and
evaluating circuit node test results.

2. The method of claim 1, wherein the step of selecting locations of the μBump groups comprises the step of determining a location substantially equidistant between the μBumps of each the μBump groups.

3. The method of claim 1, wherein a plurality of IC dice comprise an IC wafer.

4. The method of claim 3, further comprising the step of singulating from the IC wafer each of the plurality of IC dice before testing.

5. The method of claim 3, further comprising the step of singulating from the IC wafer each of the plurality of IC dice after testing.

6. An integrated circuit (IC) die, comprising:
a substrate having a plurality of electronic circuits,
a redistribution layer (RDL) on the substrate, and
a plurality of μBumps having portions thereof in the RDL and substantially perpendicular to a face thereof; and
the electronic circuits having circuit nets thereof coupled to respective groups of μBumps.

7. The IC die according to claim 6, wherein each group of μBumps forms a landing zone for a test probe tip.

8. The IC die according to claim 6, wherein each μBump comprises a conductive metal column having a first portion outside of the RDL, a cap of solder at an end of the first portion, and a second portion in the RDL.

9. The IC die according to claim 8, wherein the conductive metal column comprises multiple metal layers (Cu/Ni/Cu).

10. The IC die according to claim 8, wherein the cap of solder is selected from the group consisting of SnAg (tin-silver) and SnCu (tin-copper).

11. The IC die according to claim 8, wherein each landing zone of a group of μBumps is at a different location of the IC die and each group of μBumps is adapted for coupling to a respective one of the test probe tips.

12. The IC die according to claim 8, wherein the ends of the first portions of the columns of the plurality of μBumps are planar.

13. The IC die according to claim 7, wherein a shape of the landing zone is selected from the group consisting of round, square and rectangular, and each landing zone includes a group of at least three μBumps electrically connected together.

14. The IC die according to claim 7, wherein the test probe tip is substantially flat.

15. The IC die according to claim 7, wherein the test probe tip is substantially rounded.

16. An integrated circuit (IC) wafer, comprising:
a plurality of IC dice;
each of the plurality of IC dice comprising;
a substrate comprising a plurality of electronic circuits,
a redistribution layer (RDL) on the substrate, and
a plurality of μBumps having portions thereof in the RDL and substantially perpendicular to a face thereof; and
the electronic circuits having circuit nets thereof coupled to respective groups of μBumps.

17. The IC wafer according to claim 16, wherein each group of μBumps forms a landing zone for a test probe tip.

18. The IC wafer according to claim 17, wherein each of the landing zones is shaped for one of the test probe tips.

19. The IC wafer according to claim 17, wherein a plurality of landing zones are arranged in rows and columns on a face of each IC die.

20. The IC wafer according to claim 17, wherein a plurality of landing zones are arranged diagonally on a face of each IC die.
